(19) United States
(12) Patent Application Publication
(10) Pub. No.: US 2020/0135968 A1
(43) Pub. Date: Apr. 30, 2020

(54) LIGHT EMITTING BIPOLAR TRANSISTOR

(71) Applicant: COMMISSARIAT A L'ENERGIE ATOMIQUE ET AUX ENERGIES ALTERNATIVES, Paris (FR)

(72) Inventors: Anis Daami, Grenoble Cedex (FR); Alexandre Ferron, Grenoble Cedex (FR); Aurelien Suhm, Grenoble Cedex (FR)

(73) Assignee: COMMISSARIAT A L'ENERGIE ATOMIQUE ET AUX ENERGIES ALTERNATIVES, Paris (FR)

(21) Appl. No.: 16/668,954

(22) Filed: Oct. 30, 2019

(30) Foreign Application Priority Data
Oct. 31, 2018 (FR) 18 60072

(51) Int. Cl. H01L 33/06; H01L 33/00; H01L 33/32; H01L 33/30

(52) U.S. Cl. CPC H01L 33/06; H01L 33/0025; H01L 33/0062; H01L 33/30; H01L 33/0075; H01L 33/32

(57) ABSTRACT

A light emitting bipolar transistor, comprising at least:
first, second and third portions of doped semiconductor, forming a collector, a base and an emitter respectively of the light emitting bipolar transistor;
at least one quantum well arranged in the first portion and between two first barrier layers formed by the doped semiconductor of the first portion;
and in which the levels of the energy bands of the doped semiconductor of the first portion are higher than those of a semiconductor forming the quantum well which is configured to produce the light emission of the bipolar transistor.

### TECHNICAL FIELD

The technical field of the invention is light emitting electronic components, particularly components made with GaN or a semiconductor comprising GaN, and more generally any type III-V semiconductor. Such components are advantageously used in a light emitting device in the form of a matrix, thus forming a screen.

### State of Prior Art

The most frequently used electronic components to obtain light emission are light emitting diodes (LEDs). A LED is usually associated with an electronic circuit, for example of the CMOS type, controlling the current in the LED, in other words modulating light emission from the LED, by varying the current sent to the LED.

Other types of light emitting electronic components have been proposed, particularly with the purpose of grouping the light emitting element and a control element in the same electronic component.

Document US 2008/0240173 A1 proposes to make a bipolar transistor in which a quantum well that emits light is integrated into the base of the transistor. This integration of an emitting element into the base of a bipolar transistor is advantageous because the current circulating in the transistor is used to create light emission. Furthermore, the light emitting element and the control element are integrated into a single electronic component. However, the base of a bipolar transistor is fabricated to be very thin to facilitate the passage of charge carriers between the emitter and the collector very quickly. Since the base of the bipolar transistor is very thin, only one quantum well can be made in the base of the bipolar transistor. A larger number of quantum wells would be advantageous because this would make it possible to improve the emissive efficiency of this component.

Document US 2010/0277466 A1 discloses an alternative solution in which one or several emissive elements are integrated into a bipolar transistor, these emissive elements corresponding to emissive capacitances. However, such emissive capacitances are not well adapted for light emission within a bipolar transistor. Indeed a capacitive element comprises a dielectric material placed between two electrodes. Light emission from such an element is only possible with very high current/voltage levels, given that the bandgap of the dielectric material is energetically very large. Furthermore, the current circulating in the transistor that is direct current, cannot pass through a capacitance from one electrode to the other. Only alternating current can pass through such a capacitance. Thus, light emission is only obtained when a large electrical discharge passes through the capacitance(s) integrated into the transistor. Such operation is not optimal to correctly control light emission.

Document U.S. Pat. No. 5,153,693 proposes a semiconductor device integrating, in a same stack, a bipolar transistor and an emitting diode integrated between the growth substrate and the collector of the bipolar transistor. The transistor further integrates barrier layers inserted into the collector and serving to improve the bistability of the transistor in the absence of resistive load external to the transistor. These barrier layers make it possible to control the flow of electrical charges in the collector by controlling the passage of charges through these barrier layers by resonant tunnelling effect.

In this device, the light emission is obtained by adding, between the collector of the transistor and the growth substrate, an LED or a laser. The transistor of this device does not emit light in itself. The barrier layers used in the collector are not dedicated to trapping charge carriers to allow light emission between them.

### Presentation of the Invention

Thus there is a need to propose a new electronic component integrating a light emitting element and an element controlling this light emission, wherein the number of quantum wells is not limited by a thickness constraint within the component, and such that the light emission can be as efficient as a LED.

To achieve this, one embodiment discloses a light emitting bipolar transistor, comprising at least:
first, second and third portions of doped semiconductor, forming a collector, a base and an emitter respectively of the light emitting bipolar transistor;
at least one quantum well arranged in the first semiconducting portion and between two first barrier layers formed by the doped semiconductor of the first portion.

The levels of the energy bands of the doped semiconductor of the first portion may be higher than those of a semiconductor forming the quantum well which is configured to produce the light emission of the bipolar transistor.

It is thus proposed the integration of a quantum well, in other words an emitting element similar to a LED, in the collector of a bipolar transistor. Thus, the current that passes through the collector that corresponds to the base current multiplied by the gain of the transistor, passes through the quantum well(s) to create light emission. Therefore the light emission obtained is controlled in current through the base current of the bipolar transistor.

In the transistor, the layers used to emit light are integrated in the production of the collector itself.

Therefore this bipolar transistor forms an electronic component integrating a light emitting device and an element to control this light emission, wherein the amplified current of the transistor controls the light emission produced by the quantum well(s).

Since the collector of a bipolar transistor is reverse biased, the integration of one or several quantum wells within the collector is not a solution that would be obvious for a skilled person. A LED comprising one or several quantum wells is functional in direct biasing to have a large number of injected electrical charges to be recombined in the quantum well(s). Nevertheless, the collector of a bipolar transistor is a region used to accelerate and amplify the charge carriers injected by the emitter and that pass through the collector. In arranging one or several quantum wells in the collector, some of the electrical charges accelerated in the collector are trapped in the quantum wells(s) and can produce radiative recombinations.

The or each quantum well is formed by a layer of semiconducting material with a smaller gap that the semiconductor of the first portion (in other words the collector) in which the quantum well is arranged.

Since the first barrier layers are formed by the doped semiconductor of the first portion, and therefore do not correspond to layers of a semiconductor different from that of the first portion and arranged in the first portion, the thicknesses first barrier layers are therefore greater than a limit thickness beyond which electrical charges cannot pass through the first barrier layers by resonant tunnelling effect. This makes it possible to form a quantum well producing a light emission from the electrical charges trapped in the quantum well.

In addition, using the doped semiconductor of the collector to form the barrier layers facilitates the growth of the component itself because no major change occurs during the production of the transistor, except for the insertion of the layer(s) forming the quantum well(s) which have a lower bandgap than that of the doped semiconductor of the collector.

The transistor may be configured such that:
in a first part of the first semiconducting portion, the levels of the energy bands of the doped semiconductor of this first part have first values;
the levels of the energy bands of the doped semiconductor of the second semiconducting portion have second values different from the first values;
in a second part of the first semiconducting portion arranged between the first part of the first semiconducting portion and the second semiconducting portion, the levels of energy bands of the doped semiconductor in this second part vary and pass from the first values to the second values;
the quantum well(s) is (are) arranged in the second part of the first semiconducting portion.

In this configuration, the energy band levels of the semiconductor of the first portion which is juxtaposed with the quantum well(s) are higher than those of the semiconductor forming the quantum well(s).

The above characteristics relating to the levels of the energy bands of the semiconductors are obtained in the absence of biasing of the transistor, that is to say when the energy bands of the materials are not curved by this biasing.

The light emitting bipolar transistor may also comprise a second barrier layer arranged in the second part of the first semiconducting portion and such that the quantum well(s) is (are) located between the second barrier layer and the second semiconducting portion. This second barrier layer makes it possible to have an avalanche of carriers in the collector and to increase the number of electrical charges trapped in the quantum well(s), and therefore to obtain higher light emission in exchange for a slight reduction in the gain of the transistor.

The light emitting bipolar transistor may comprise several quantum wells arranged in the first semiconducting portion, each quantum well possibly being separated from a neighbouring quantum well by at least one intermediate barrier layer formed by the doped semiconductor of the first semiconducting portion.

The light emitting bipolar transistor may be such that:
the first, second and third semiconducting portions comprise GaN (with in this case the first barrier layers and the possible intermediate barrier layer(s) which comprise GaN), and the quantum well(s) comprise(s) InGaN, or
the first, second and third semiconducting portions comprise GaAs (with in this case the first barrier layers and the possible intermediate barrier layer(s) which comprise GaAs), and the quantum well(s) comprise(s) InGaAs, or
the first, second and third semiconducting portions comprise InP (with in this case the first barrier layers and the possible intermediate barrier layer(s) which comprise InP), and the quantum well(s) comprise(s) GaInP, or
the first, second and third semiconducting portions comprise AlGaAs (with in this case the first barrier layers and the possible intermediate barrier layer(s) which comprise AlGaAs), and the quantum well(s) comprise(s) InAlGaAs.

The use of GaN to form the first, second and third portions makes it possible to obtain a transistor adapted to function with high powers. Furthermore, when the first, second and third portions comprise GaN and the quantum well(s) comprise InGaN, the light emission obtained may correspond to a blue or green or violet light emission depending on the rate or the concentration of indium in the InGaN in the quantum well(s) or even light emission in the ultraviolet range when the rate or the concentration of indium in the InGaN of the quantum well(s) is low (for example less than about 5%).

The use of GaAs or InP to form the first, second and third portions and InGaAs or GaInP to form the quantum well(s) enable to obtain light emission in the infrared range.

The use of AlGaAs to form the first, second and third portions and InAlGaAs to form the quantum well(s) enable to obtain red-coloured light emission.

The atomic composition of the doped semiconductor of the first semiconducting portion may be different from the atomic composition of the doped semiconductor of the second and/or the third semiconducting portion(s). This configuration can be used to obtain a bipolar transistor with heterojunction. The semiconductor of the first portion in which the quantum well(s) is (are) integrated may be chosen independently from that used to form the second and the third portions. It is thus possible to optimise the gain and/or light emission output by the transistor.

Another embodiment relates to a light emitting device comprising:
at least one light emitting bipolar transistor as described above,
at least one circuit for biasing the light emitting bipolar transistor(s), configured to bias the light emitting bipolar transistor(s) in common emitter.

This device may comprise a matrix of light emitting bipolar transistors forming a screen.

Another embodiment relates to a method of making a light emitting bipolar transistor as described above, in which the first, second and third semiconducting portions and the quantum well(s) are made using epitaxy and doping steps.

### BRIEF DESCRIPTION OF THE DRAWINGS

This invention will be better understood after reading the description of example embodiments given purely for information and that is in no way limitative with reference to the appended drawings on which:

FIG. 1 diagrammatically shows a bipolar transistor comprising an integrated light emitting element according to a particular embodiment;

FIG. 2 diagrammatically shows a particular example embodiment of a bipolar transistor comprising an integrated light emitting element;

FIG. 3 shows the currents i_{B} and i_{C} and the radiative recombinations rate obtained in a light emitting bipolar transistor according to a particular embodiment, as a function of the value of an electrical potential applied on the base of the transistor;

FIG. 4 shows the gain obtained in a light emitting bipolar transistor according to a particular embodiment, in other words the value of the collector current i_{C} as a function of the value of the base current i_{B};

FIG. 5 shows the radiative recombination rate obtained in a light emitting bipolar transistor according to a particular embodiment, as a function of the value of the base current i_{B};

FIG. 6 shows the emission spectrum obtained in a light emitting bipolar transistor according to a particular embodiment;

FIG. 7 shows the energy bands within the first and second semiconducting portions of the light emitting bipolar transistor according to a particular embodiment, in the presence of the second barrier layer;

FIG. 8 shows the energy bands within the first and second semiconducting portions of the light emitting bipolar transistor according to a particular embodiment, in the absence of the second barrier layer;

FIG. 9 shows the gain obtained in a light emitting bipolar transistor according to a particular embodiment, in other words the value of the collector current i_{C} as a function of the value of the base current i_{B}, with and without a barrier layer interposed between the quantum wells and the collector of the transistor;

FIG. 10 shows the radiative recombination rate obtained in a light emitting bipolar transistor according to a particular embodiment, as a function of the base current i_{B}, with and without a barrier layer interposed between the quantum wells and the transistor collector;

FIG. 11 diagrammatically shows a light emitting device according to a particular embodiment, comprising a matrix of light emitting bipolar transistors;

FIGS. 12 to 22 show the steps in a particular embodiment of a method for making a light emitting bipolar transistor.

Identical, similar or equivalent parts of the different figures described below have the same numeric references to facilitate comparison between the different figures.

The different parts shown on the figures are not necessarily all at the same scale, to make the figures more easily understandable.

The different possibilities (variants and embodiments) must be understood as not being mutually exclusive and can be combined with each other.

### DETAILED PRESENTATION OF PARTICULAR EMBODIMENTS

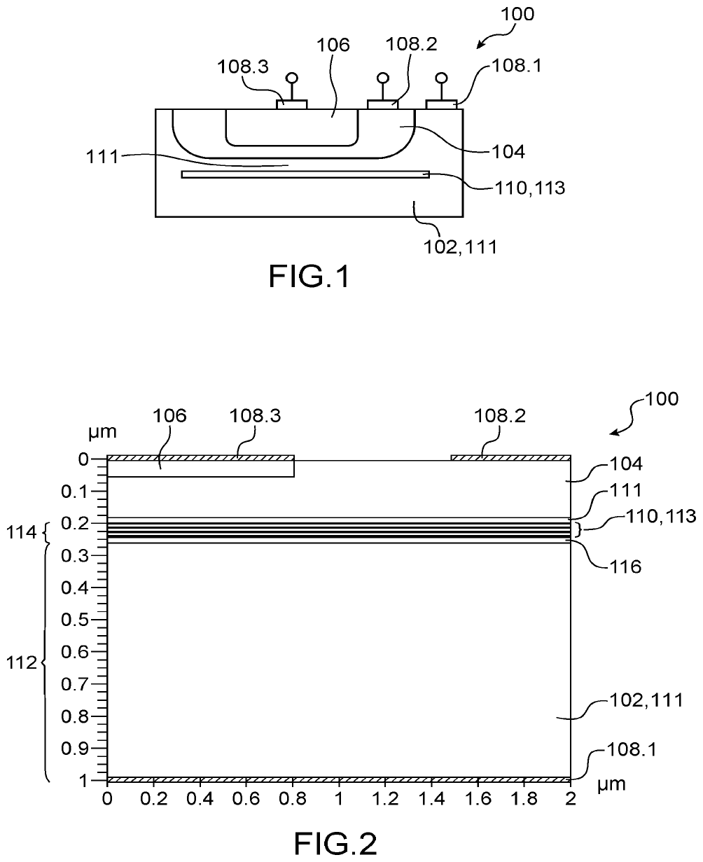

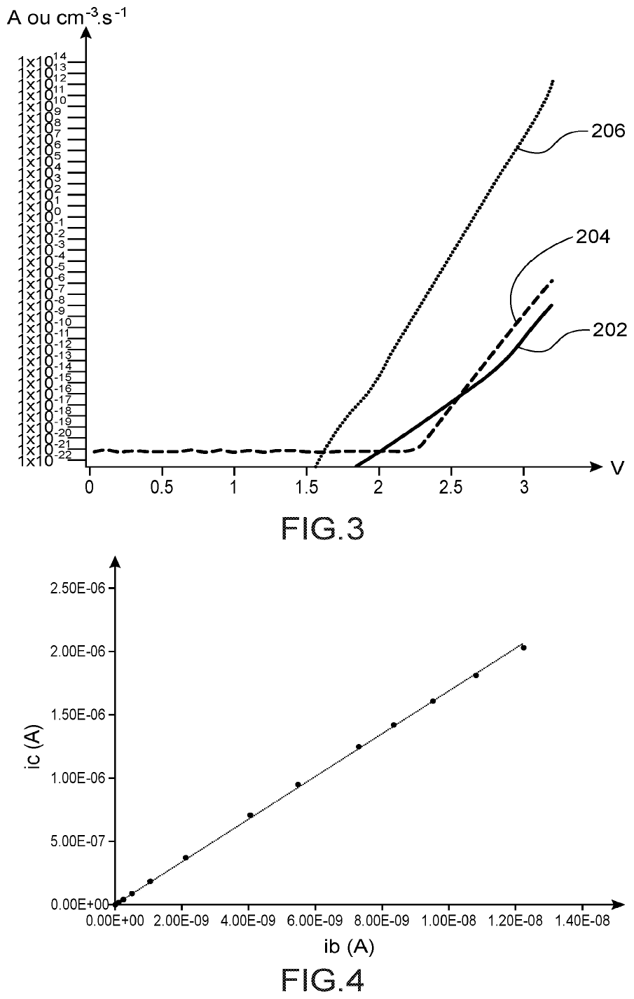

A light emitting bipolar transistor 100 made according to one particular embodiment is described below with reference to FIGS. 1 and 2 that diagrammatically show the principal of such a transistor.

The transistor 100 comprises a first semiconducting portion 102 forming the collector of the transistor 100. When the transistor 100 is of the npn type, the semiconductor of this first portion 102 is n doped, and when the transistor 100 is of the pnp type, the semiconductor of this first portion 102 is p doped. The doping level of this first portion 102 may for example be between about 5×10¹⁷ cm⁻³ and 1×10¹⁸ cm⁻³. The thickness of the first portion 102 may for example be between about 300 nm and 1000 nm.

The transistor 100 comprises a second semiconducting portion 104 arranged in contact with the first portion 102 and forming the base of the transistor 100. When the transistor 100 is of the npn type, the semiconductor of this second portion 104 is p doped, and when the transistor 100 is of the pnp type, the semiconductor of this second portion 104 is n doped. The doping level of this second portion 104 may for example be between about 1×10¹⁸ cm⁻³ and 5×10¹⁸ cm⁻³. The thickness of the second portion 104 may for example be between about 100 nm and 200 nm.

The transistor 100 comprises a third semiconducting portion 106 arranged in contact with the second portion 104 and separated from the first portion 102 by the second portion 104. The third portion 106 forms the emitter of the transistor 100. When the transistor 100 is of the npn type, the semiconductor of this third portion 106 is n doped, and when the transistor 100 is of the pnp type, the semiconductor of this third portion 106 is p doped. The doping level of this second portion 106 may for example be between about 1×10¹⁹ cm⁻³ and 5×10¹⁹ cm⁻³. The thickness of the third portion 106 may for example be between about 50 nm and 100 nm.

The transistor 100 in the particular embodiment described herein is a homojunction transistor.

The semiconductor of the portions 102, 104, 106 is of the III-V type, in other words it comprises one or several elements in column III and one or several elements in column V in the periodic table of elements. Advantageously, the semiconductor in portions 102, 104 and 106 is GaN. As a variant, this semiconductor could be GaAs, InP or AlGaAs. However, other semiconductors can be used to make these portions 102, 104, 106, depending on the required properties for the transistor 100.

The transistor 100 comprises three contacts 108.1-108.3, each arranged in contact with one of the three portions 102, 104 and 106 and forming electrical accesses to these portions 102, 104, 106. Each of the contacts 108.1-108.3 comprises an electrically conducting material. On the diagrammatic view shown in FIG. 1, the three contacts 108.1-108.3 are arranged on the front face of the transistor 100. On FIG. 2, the first contact 108.1 connected to the collector of the transistor 100 is arranged on the back face of the transistor 100 and the second and third contacts 108.2, 108.3 connected to the base and to the emitter of the transistor 100 are arranged on the front face of the transistor 100.

The transistor 100 also comprises a light emitting element comprising one or several quantum wells 110 made within the first portion 102, in other words within the collector of the transistor 100. This or these quantum wells 110 are formed by one or several semiconductor layers, the gap of which is less than the gap of the semiconductor of the first portion 102. For example, when the first portion 102 comprises GaN, the quantum well(s) 110 correspond(s) for example to one or several layers of InGaN. When the first portion 102 comprises GaAs, the quantum well(s) 110 comprise(s) for example InGaAs. When the first portion 102 comprises InP, the quantum well(s) 110 comprise(s) for example GaInP. When the first portion 102 comprises AlGaAs, the quantum well(s) 110 comprise(s) for example InAlGaAs.

Each semiconducting layer forming a quantum well 110 is for example between 2 nm and 4 nm thick.

The transistor 100 in the embodiment described herein comprises three quantum wells 110. In general, the transistor 100 comprises a number of quantum wells equal to between 1 and 5.

The quantum well 110, or a set formed by the quantum wells 110, is arranged between two first barrier layers 111 formed by the doped semiconductor of the first portion 102, and more specifically by the whole of the doped semiconductor of the first portion 102 located on each side of the quantum well 110 or on each side of the set formed by the quantum wells 110. For example, when the first portion 102 comprises GaN and the quantum well or wells 110 correspond for example to one or several layers of InGaN, the two first barrier layers 111 are formed by all the GaN of the first portion 102 located on each side of the quantum well 110 or of the set formed by the quantum wells 110. When the first portion 102 comprises GaAs and the quantum well or wells 110 comprise for example InGaAs, the two first barrier layers 111 are formed by all the GaAs of the first portion 102 located on each side of the quantum well 110 or of the set formed by the quantum wells 110. When the first portion 102 comprises InP and the quantum well or wells 110 comprise for example GaInP, the two first barrier layers 111 are formed by all the InP of the first portion 102 located on each side of the quantum well 110 or of the set formed by the quantum wells 110. When the first portion 102 comprises AlGaAs and the quantum well or wells 110 comprise, for example, InAlGaAs, the two first barrier layers 111 are formed by all the AlGaAs of the first portion 102 located on each side of the quantum well 110 or of the set formed by the quantum wells 110.

Since the first barrier layers 111 are formed by the doped semiconductor of the first portion, the thicknesses of the first barrier layers 111 are therefore greater than a limit thickness beyond which electrical charges cannot pass through the first barrier layers by resonant tunnelling effect, this limit thickness being for example equal to 10 nm.

In general, the thickness of each of the two first barrier layers 111 between which is the quantum well 110 or the set of quantum wells 110 is located is equal to several tens of nanometers (for example at least 20 nm), or even one or several hundred nanometers (for example at least 100 nm). Thus, the charges trapped in the quantum well 110 or one of the quantum wells 110 cannot pass through the first barrier layers 111.

When the transistor 100 comprises several quantum wells 100, two neighbouring quantum wells are spaced apart from one another by an intermediate barrier layer 113 whose thickness is smaller than that of one of the two first barrier layers 111, and by example less than about 20 nm or even less than about 10 nm.

The semiconductors of the first portion 102 and of the quantum well(s) 110 are such that they comprise at least one element in column III and at least one element in column V in common.

The quantum well(s) 110 is (are) arranged in a part of the collector of the transistor 100 located close to the base of the transistor 100. Considering the p-n junction formed by the base and the collector of the transistor 100, the collector is formed from two parts:
a first part 112 in which the level of the energy bands of the semiconductor have first values;
a second part 114 located between the first part 112 and the base of the transistor 100, in which the levels of the energy bands of the semiconductor of this second part vary from first values to second values different from the first values and that correspond to the values of the levels of energy bands of the semiconductor in the base of the transistor 100.

The quantum well(s) 110 is (are) arranged in this second part 114 of the first portion 102 that forms the space charge region, or depletion region, in which the electrical field is intense and drains the charge carriers that can therefore be trapped in the quantum wells and recombine to emit light.

In general, the location of the quantum well or wells 110 in a portion of the collector of the transistor 100 located near the base of the transistor 100 means that the doped semiconductor thickness of the first portion 102 located on a first side of the quantum well or wells, between the base of the transistor 100 and the quantum well or quantum wells 110, is smaller than that of the doped semiconductor of the first portion 102 located on a second side opposite to the first side, that is to say on the other side of the quantum well or wells 110.

In the particular embodiment described herein, the transistor 100 also comprises a second barrier layer 116. This second barrier layer 116 is arranged in the second part 114 of the first portion 102 and is such that the quantum well(s) 110 is (are) located between the second barrier layer 116 and the second portion 104. The gap of the semiconductor of the second barrier layer 116 is larger than the gap of the semiconductor of the second portion 104. For example, when the second portion 104 comprises GaN, the second barrier layer 116 comprises AlGaN. This second barrier layer 116 limits the leakage of charge carriers from the collector and increases the number of electrical charges trapped in the quantum well(s) 110, and therefore a higher light emission can be obtained, in exchange for a slight reduction in the gain β, or h₂₁, of the transistor.

The transistor 100 is used for example in a device biasing the transistor 100 in common emitter. In such a setup, the value of the current i_{C} passing through the collector of the transistor 100 is equal to the value of the current i_{g} circulating in the base of the transistor 100 multiplied by the gain β of the transistor 100. The light emission made by the quantum well(s) 110 depends on the value of the current i_{C}. Therefore it is possible to control this light emission by controlling the current i_{B}.

FIG. 2 shows the structure of the transistor 100 used to make the simulations described below. The characteristics of this modelled transistor 100 are:
npn type transistor 100;
portions 102, 104 and 106 comprising GaN;
doping of the first portion 102 equal to about 8×10¹⁷ cm⁻³;
doping of the second portion 104 equal to about 1×10¹⁸ cm³;
doping of the third portion 106 equal to about 4×10¹⁹ cm⁻³;
thickness of the first portion 102 equal to about 800 nm;
thickness of the third portion 106 equal to about 50 nm;
thickness of the second portion 104 equal to about 200 nm;
total thickness of the transistor 100 equal to about 1 μm;
three quantum wells 110 each comprising a layer of In_{0.1}Ga_{0.9}N with a thickness of about 2 nm, the quantum wells 110 being separated one from the other by intermediate barrier layers 113 comprising doped GaN and a thickness of about 5 nm;
two first barrier layers 111 formed by the semiconductor of the first portion 102 (doped GaN) lying on each side of the set comprising the quantum wells 110 and the intermediate barrier layers 113 arranged between the quantum wells, thickness of each of these two first barrier layers 111 being equal to several tens or hundreds of nm;
second barrier layer 116 comprising AlGaN, with a thickness equal to about 12 nm, and the same doping as the semiconductor in the first portion 102.

In the In_{X}Ga_{1-X}N notation used above, X represents the composition in indium or the concentration of indium in the material, in other words the proportion of indium relative to the total quantity of indium and gallium in the In_{X}Ga_{1-X}N.

A simulation of the electrical behaviour of this transistor 100 is made by biasing it in common emitter mode, by applying a first electrical potential V_{E}=0V on the emitter, a second electrical potential V_{c}=5V on the collector, and varying a third electrical potential V_{B} applied on the base between 0 V and 3.2 V.

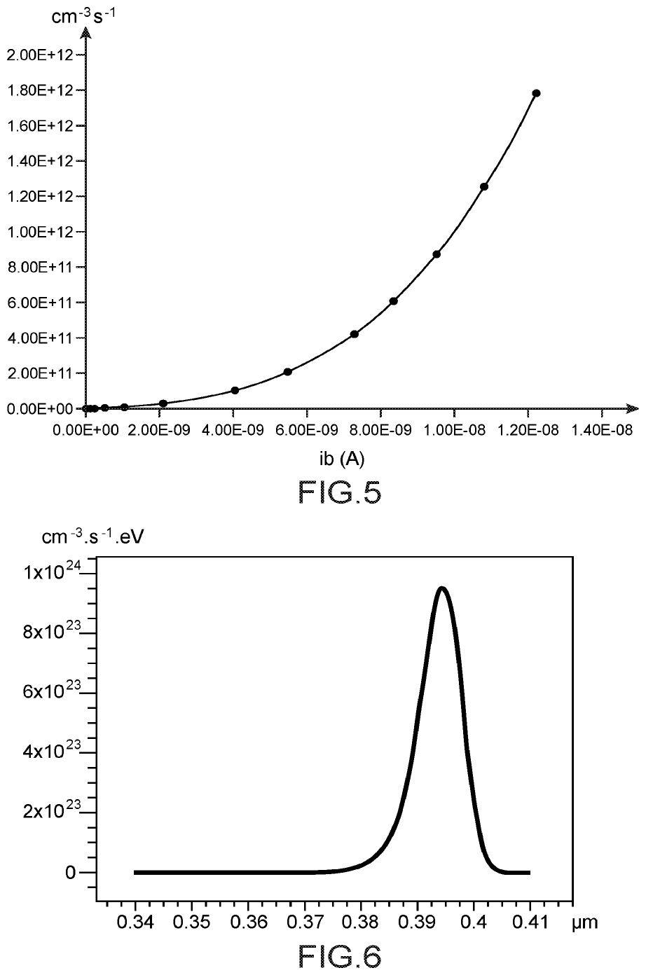

FIG. 3 shows the base current i_{B} (curve 202), the collector current i_{C} (curve 204) and the radiative recombination rate (curve 206) obtained during this simulation. Curves 202 and 204 drawn on FIG. 3 show that in such a configuration, the transistor 100 amplifies the current (the current i_{C} becomes larger than the current i_{B}) when the third electrical potential V_{B} is greater than or equal to about 2.5 V. Furthermore, curve 206 shows that the radiative recombination rate obtained in the quantum wells 110 of this transistor 100 starts to become significant when V_{B} is greater than or equal to about 2.5 V, and increases as a function of the current i_{B} injected into the transistor 100.

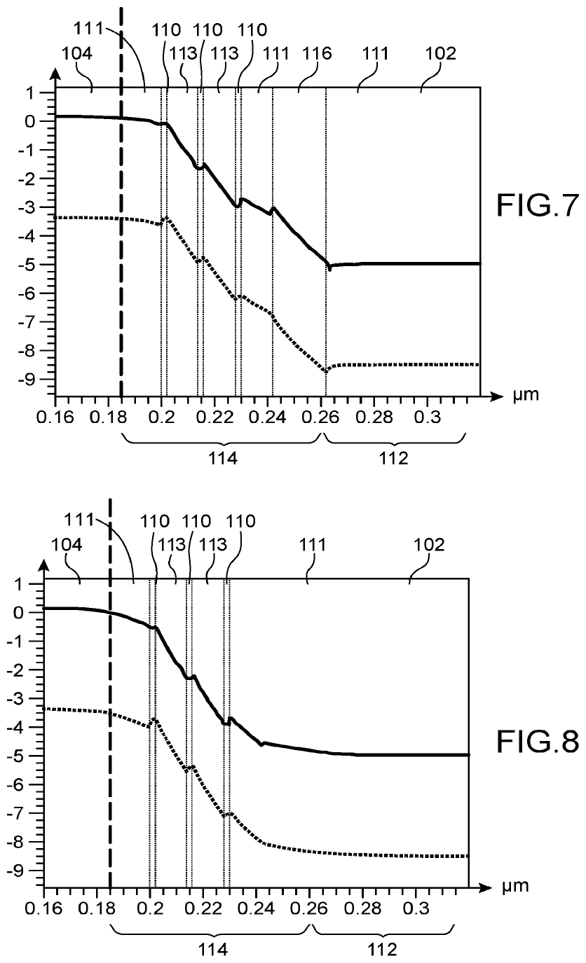

FIG. 4 shows the gain β of the modelled transistor 100, corresponding to the i_{C}/i_{B} ratio obtained under the biasing conditions mentioned above.

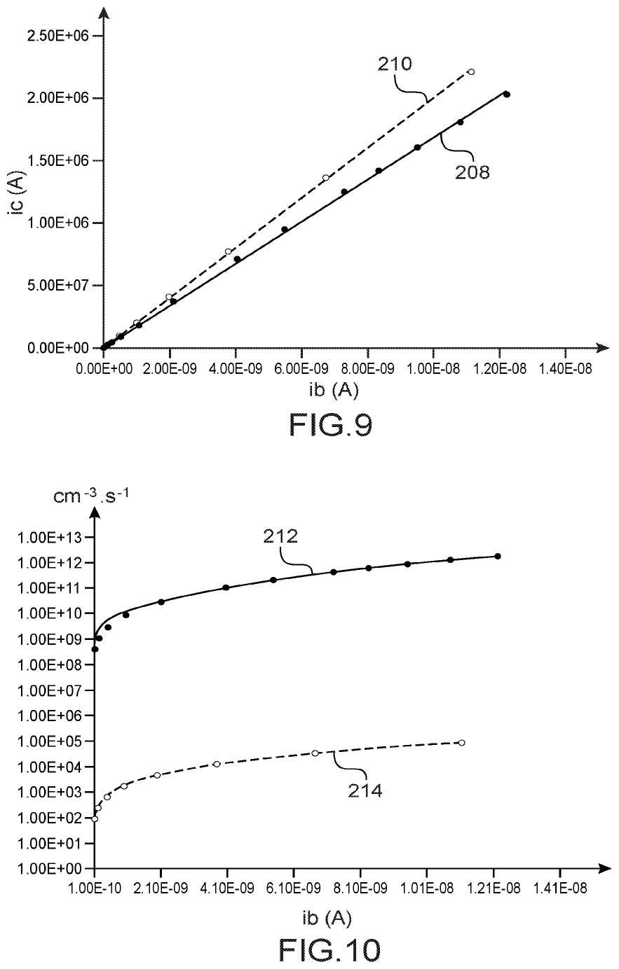

FIG. 5 shows the radiative recombination rate obtained by varying the value of the current i_{B}.

Therefore, the curves in FIGS. 3 to 5 clearly show that:
the amplification function performed by the transistor 100 is not modified by the presence of the quantum wells 110, and that
light emission is controlled in current as a function of the current i_{B} injected into the transistor 100.

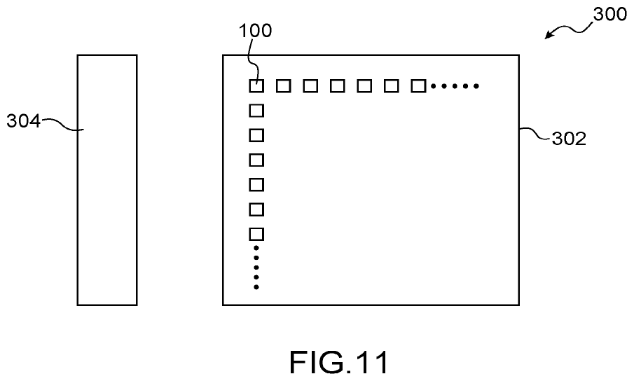

The emission spectrum of the transistor 100 according to this example particular embodiment, is shown on FIG. 6. This figure shows that the spectrum of light emitted from the quantum wells 110 is centred around a frequency equal to about 395 nm (violet coloured light). The central frequency of the spectrum of the light emitted by the quantum wells 110 depends particularly on the rate, or content, of indium in the semiconductor of the quantum wells 110. The indium rate and the arrangement of the quantum wells 110 can be optimised so as to obtain emission of a particular colour in the visible range (for example blue, green, violet or red). For example, to emit green or blue or violet light, the semiconductor of the quantum wells 110 is advantageously InGaN. To emit in the ultraviolet range, the indium rate of InGaN is chosen to be less than or equal to about 5%. To emit red light, the semiconductor of the quantum wells 110 is for example InAlGaAs. To emit in the infrared range, the semiconductor of the quantum wells 110 is for example InGaAs or GaInP.

In the particular embodiment described above, the transistor 100 comprises the second barrier layer 116 that limits the leakage of charge carriers in the collector of the transistor 100. According to one variant embodiment, the transistor 100 does not necessarily comprise a second barrier layer 116.

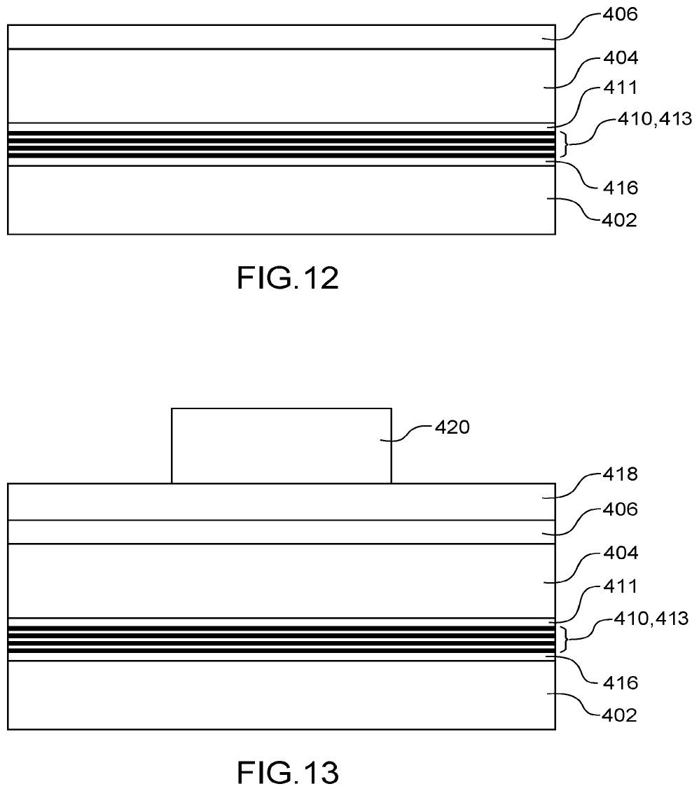

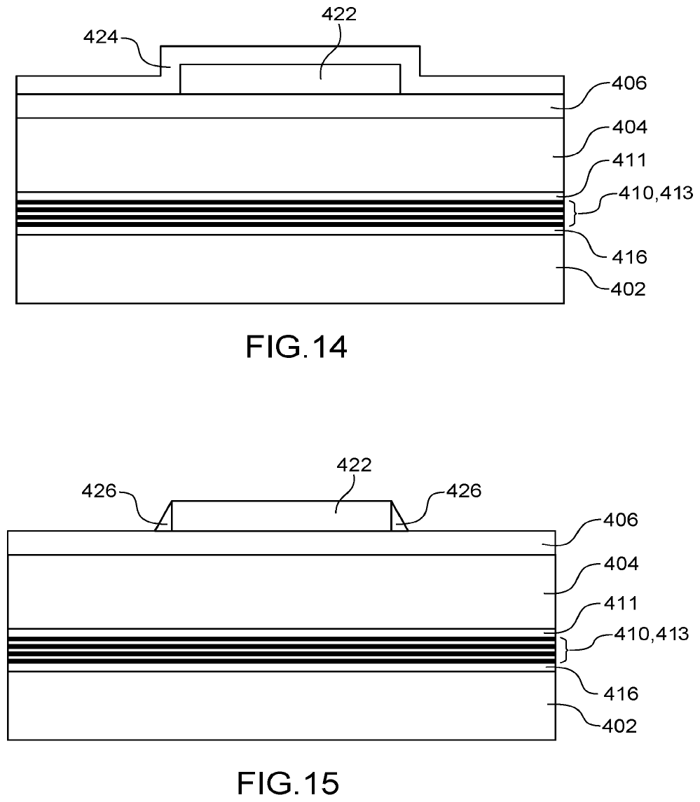

FIG. 7 shows energy bands within the transistor 100 in the presence of the second barrier layer 116, while FIG. 8 shows energy bands within the transistor 100 in the absence of the second barrier layer 116. On these two figures, the references previously used to designate the different elements of the transistor 100 are shown on FIGS. 7 and 8 to designate levels of energy bands in these different elements.

FIGS. 7 and 8 also illustrate the distinction made in the first portion 102 between the first part 112 in which the levels of the energy bands of the semiconductor have first values, and the second part 114 in which the levels of the energy bands of the semiconductor vary from first values to second values that correspond to values of levels of energy bands of the semiconductor in the second portion 104.

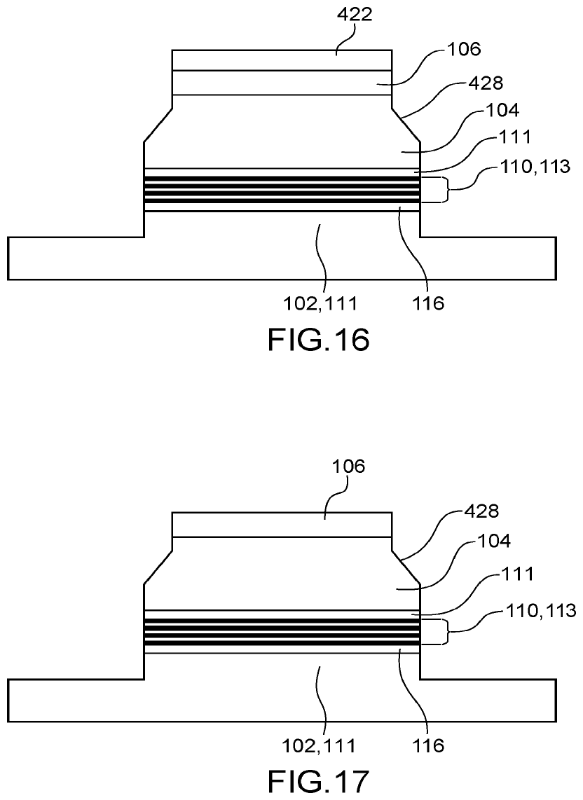

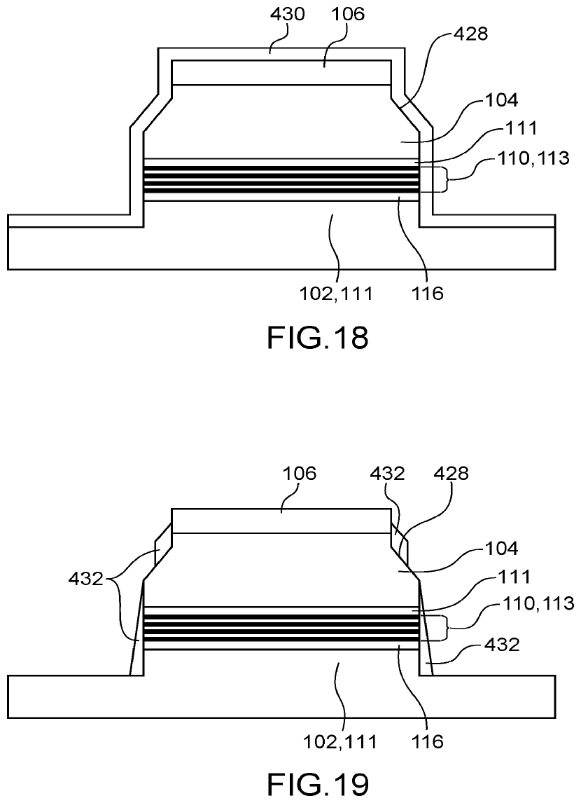

FIG. 9 shows the gain of the transistor 100 obtained with the second barrier layer 116 (curve 208) and without the second barrier layer 116 (curve 210). FIG. 10 shows the radiative recombination rate obtained in the quantum wells 110 of the transistor 100 obtained with the second barrier layer 116 (curve 212) and without the second barrier layer 116 (curve 214).

When the transistor 100 does not comprise the second barrier layer 116, a larger current amplification is obtained, the gain β being equal to about 200. On the other hand, light emission obtained in this case is weaker, due to the drop in the radiative recombination rate in the quantum wells 110. This is explained by the fact that in the absence of this second barrier layer 116, the charge carriers are attracted more on the side of the contact of the collector of the transistor 100 and therefore a smaller quantity of charge carriers recombine in the quantum wells 110. Thus, the thickness and the position of the second barrier layer 116 within the first portion 102, correspond to two variables used to adjust the gain of the transistor 100 and the intensity of light emission from the transistor 100.

In the particular embodiment described above, the transistor 100 is a homojunction transistor, the semiconducting material of the collector (first portion 102) being similar to the material of the base and the emitter (second and third portions 104 and 106). As a variant, it is possible that the transistor 100 is a heterojunction transistor, the semiconducting material of the collector then being different from the material of the base and/or the emitter. Such a heterojunction transistor comprises for example an emitter containing AlGaN, a base containing AlGaN and a collector containing GaN.

The transistor 100 described above can be used as a LED, by injecting current into the base of the transistor 100 to control its light emission.

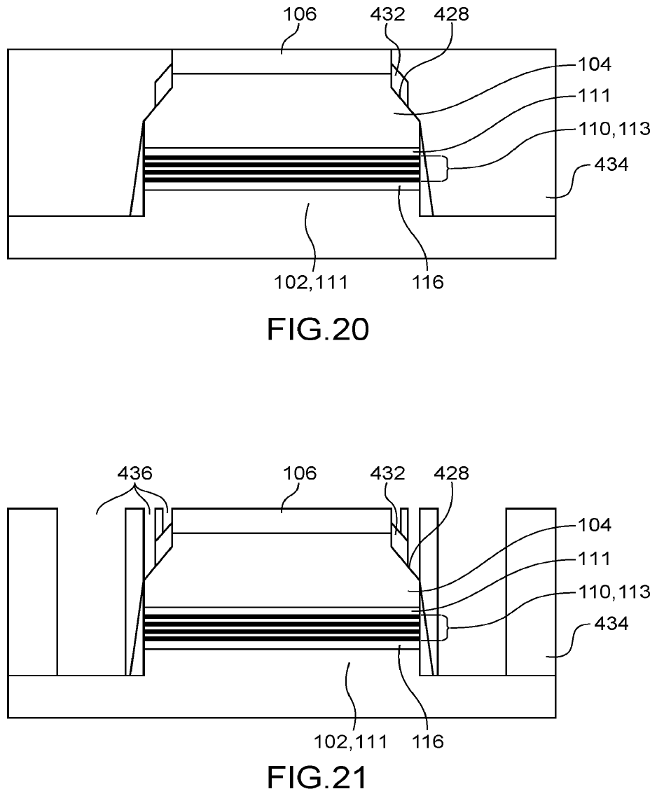

FIG. 11 diagrammatically shows a light emitting device comprising a matrix 302 of light emitting bipolar transistors 100. This matrix 302 forms a screen. The device 300 also comprises a circuit 304 for biasing the transistors 100 configured to bias the transistors 100 in common emitter.

The transistor 100 described above is made by using epitaxy steps to form the first, second and third semiconductor portions and the quantum well(s).

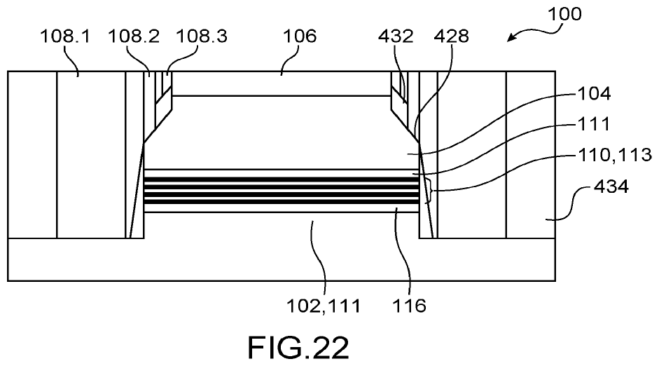

One method of fabricating the transistor 100 according to one particular embodiment is described below with reference to FIGS. 12 to 22. The transistor 100 fabricated according to this method is for example designed to act as a micro-pixel within a matrix of transistors 100 forming a screen.

The transistor 100 is for example made from a substrate comprising a GaN layer arranged on a semiconducting support layer (substrate), for example silicon or sapphire. The different layers used to form the first, second and third portions 102, 104, 106 of the transistors 100, and the quantum wells 110 and the second barrier layer 116, if there is one, are made on this substrate, for example by epitaxy such as a MOCVD (“Metallo-Organic Chemical Vapor Deposition”) type deposit. The different N and P dopings of the portions 102, 104, 106 can be made in in-situ when these materials are deposited. FIG. 12 shows the different layers thus formed:
layer 402 intended to form the collector of the transistors 100 and one of the two first barrier layers 111,
layer 416 arranged on the layer 402 and intended to form the second barrier layer 116 of the transistors 100,
alternating stack of layers 410 and 411 arranged on the layer 416 (or on the layer 402 if the layer 416 is not present) and intended to form the quantum wells 110 and the intermediate barrier layers 113 of the transistors 100,
layer 411 intended to form the other of the two first barrier layers 111,
layer 404 intended to form the base of the transistors 100,
layer 406 intended to form the emitter of the transistors 100.

The characteristics of these layers (thickness, dopings) correspond to the characteristics required for the different portions and the different elements of the transistors 100.

Starting from the stack of layers produced, etching steps are then implemented to form the contacts 108.1-108.3. These etchings are made at different levels to be able to make separate contacts on the emitter, the base and the collector of the transistors 100. An example embodiment to form such contacts is described below (however other techniques can be used to form these contacts).

A layer 418 that will form a hard mask and comprising for example SiN and/or SiO₂ is deposited on the layer 406.

A photosensitive resin is then deposited on the layer 418. A photolithography step is then implemented so that remaining portions 420 of resin form the pattern of the hard mask that will define the different portions of material of each of the transistors 100 (singularisation step of the transistors 100). The structure obtained at this stage of the process is shown in FIG. 13.

The layer 418 is then etched anisotropically according to the pattern defined by the remaining portions 420 of resin, the remaining portions of this layer 418 forming the hard mask 422.

The remaining resin portions 420 are then removed. A layer 424 that will form spacers against the lateral flanks of the hard mask 422 is then deposited using a conformal deposition step, for example by CVD (chemical vapour deposition) such as a PECVD deposition (plasma enhanced chemical vapour deposition), ALD (atomic layer deposition), etc. The structure obtained at this stage of the process is shown in FIG. 14.

Anisotropic etching of the layer 424 is then implemented selectively with regard to the materials present under this layer, in other words with regard to the materials in layers 402, 416, 410, 413, 411, 404 and 406, and with regard to the hard mask 422, forming spacers 426 against the lateral flanks of the hard mask 422 (see FIG. 15).

Anisotropic etching is then implemented to form stacks of portions each forming a transistor 100, starting from the layers present. The spacers 426 are consumed progressively, forming portions 102, 104, 106, 110, 111 and 116 in the form of a stack (shown on FIG. 16) comprising a shoulder 428 formed at the base (second portion 104) of the transistor 100 that will subsequently form the electrical contact 108.2 of the base. The thickness of the spacers 426 is optimised to create this shoulder 428 in the second portion 104.

The remaining portions of the hard mask 422 are then removed (see FIG. 17).

Another method of obtaining the profile shown on FIG. 17 consists of successively implementing two photolithography steps, etching and stripping (removal of the hard mask). In this case, the two photolithography levels need to be correctly aligned and the resin must be thick enough to cover the step obtained during the first etching (emitter material and stop in the base).

The contact regions of the emitter and of the base should be electrically isolated so that the electrical contacts of the transistor 100 can be made.

To achieve this, a layer 430 of dielectric material (for example Al₂O₃, SiN, SiO₂, etc.) is deposited that will isolate the contacts of the emitter and of the base of the transistor 100 (see FIG. 18). The material of the layer 430 is chosen such that the dielectric permittivity and the breakdown voltage of this material are compatible with the distances between the contacts and the working voltage. This layer 430 is formed by a conformal deposition, for example by CVD such as a PECVD or ALD deposition.

Anisotropic etching of the dielectric material of the layer 430 is then implemented. Only the spacers 432, corresponding to remaining portions of this layer 430, are kept on the lateral flanks of the stack, so that the base can be isolated from the emitter of the transistor 100 (see FIG. 19). The profile of the shoulder 428 is formed with a slope enabling conservation of the dielectric material of the layer 430 to form the spacers 432.

A dielectric layer 434, for example comprising SiO₂, is then deposited on the entire fabricated structure. Chemical-mechanical planarization (CMP) is then implemented to form an access to the upper surface of the third portion 106 (see FIG. 20).

Photolithography and etching steps are then implemented to make contacts on the emitter, the base and the collector of the transistor 100. The dielectric material of the layer 434 is etched selectively with regard to the semiconductor(s) present in the fabricated stack, forming accesses 436 to portions 102, 104 and 106 through the layer 434. The resin used for photolithography is then eliminated (see FIG. 21).

The contacts 108.1, 108.2 and 108.3 are then formed by depositing one or several electrically conducting materials, in this case metal, in the accesses 436. According to one example embodiment, these contacts 108 are formed by depositing firstly a TiN layer and if necessary a Cu layer, by CVD deposition. An electrolysis of Cu or W is then used to fill the remaining volume in the accesses 436. A CMP is then implemented to eliminate the Cu or W projecting from the accesses 436. Finally, the TiN is etched.

A first routing level can be made with these steps (for example putting the emitters of different transistors in common) during the photolithography and etching of the dielectric layer 434.

1. A light emitting bipolar transistor, comprising at least:
first, second and third portions of doped semiconductor, forming a collector, a base and an emitter respectively of the light emitting bipolar transistor;
at least one quantum well arranged in the first portion and between two first barrier layers formed by the doped semiconductor of the first portion,
and in which the levels of the energy bands of the doped semiconductor of the first portion are higher than those of a semiconductor forming said at least one quantum well which is configured to produce the light emission of the bipolar transistor.

2. The light emitting bipolar transistor according to claim 1, wherein:
in a first part of the first portion, the levels of the energy bands of the doped semiconductor of this first part have first values;
the levels of the energy bands of the doped semiconductor of the second portion have second values different from the first values;
in a second part of the first portion arranged between the first part of the first portion and the second portion, the levels of energy bands of the doped semiconductor in this second part vary passing from the first values to the second values;
said at least one quantum well is arranged in the second part of the first portion.

3. The light emitting bipolar transistor according to claim 2, also comprising a second barrier layer arranged in the second part of the first portion and such that said at least one quantum well is located between the second barrier layer and the second portion.

4. The light emitting bipolar transistor according to claim 1, comprising several quantum wells arranged in the first portion, and such that each quantum well is separated from a neighbouring quantum well by at least one intermediate barrier layer formed by the doped semiconductor of the first portion.

5. The light emitting bipolar transistor according to claim 1, wherein:
the first, second and third portions comprise GaN, and said at least one quantum well comprises InGaN, or
the first, second and third portions comprise GaAs, and said at least one quantum well comprises InGaAs, or
the first, second and third portions comprise InP, and said at least one quantum well comprises GaInP, or
the first, second and third portions comprise AlGaAs, and said at least one quantum well comprises InAlGaAs.

6. The light emitting bipolar transistor according to claim 1, wherein the atomic composition of the doped semiconductor of the first portion is different from the atomic composition of the doped semiconductor of the second and/or the third portion(s).

7. A light emitting device comprising:
at least one light emitting bipolar transistor according to claim 1,
at least one circuit for biasing said at least one light emitting bipolar transistor, configured to bias said at least one light emitting bipolar transistor in common emitter.

8. The light emitting device according to claim 7, comprising a matrix of light emitting bipolar transistors forming a screen.

9. A method of making a light emitting bipolar transistor according to claim 1, in which the first, second and third portions and said at least one quantum well are made using epitaxy and doping steps.
